(19) United States
(12) Patent Application Publication
(10) Pub. No.: US 2008/0315260 A1
(43) Pub. Date: Dec. 25, 2008

(54) Diode Structure

(76) Inventor: Russell Duane, Country Cork (IE)

Correspondence Address: PATTERSON & SHERIDAN L.L.P. NJ Office, 595 SHREWSBURY AVE, STE 100, FIRST FLOOR, SHREWSBURY, NJ, 07702, US

(21) Appl. No.: 11/909,146

(22) PCT Filed: Mar. 22, 2006
(86) PCT No.: PCT/IE2006/000017

§ 371 Date: Sep. 19, 2007

(30) Foreign Application Priority Data
Mar. 22, 2005 (IE) 2005/0155

(51) Int. Cl. H01L 29/70; H01L 21/329

(52) U.S. Cl. 257/212; 438/141; 257/E29.172; 257/E21.357

(57) ABSTRACT

An open-base semiconductor diode device has an emitter, base, and collector layers. The layers are configured and doped such that the device has an IV characteristic with: i. a punchthrough region beginning at a voltage Vₚₜ with positive resistance, followed by, and ii. an avalanche region including a positive resistance stage beginning with conductivity modulation at V_{crit} and I_{crit} and having a resistance R_{crit}, iii. wherein the values of V_{crit}, I_{crit} and R_{crit} are set according to the layer configuration and doping. The device may have a double-base structure, and the width of a lower-doped base region may be minimised such that current density J_{crit} at which the conductivity modulation occurs due to avalanche is increased. In one example, the device comprises a N-N+ or a P-P+ double-emitter. Thickness of N− or P− layers may be minimised such that the current-carrying capability is maximised and the doping of this layer does not affect the current-carrying capability of the device.

### FIELD OF THE INVENTION

The invention relates to a back-to-back diode structure, also termed an open base structure and to the manner in which it is designed and operated. This structure has electrical contact to the top and bottom regions but the middle region is not contacted. It relates particularly, but not exclusively, to clamping diodes for voltage and current suppression.

### PRIOR ART DISCUSSION

The Zener diode is the most commonly used discrete semiconductor device for overvoltage and overcurrent protection of solid state circuits. However, at low voltages, the leakage current and capacitance of a Zener diode is too high for many mobile and high frequency applications. The reason for this higher current and capacitance is due to the breakdown mechanism changing from avalanche to band-to-band tunneling for low voltages (<4V). The band-to-band tunneling mechanism requires much higher doping levels which result in the increased capacitance. The increase in leakage current is due to the higher positive differential resistance associated with this mechanism.

Other devices have been pursued for low voltage applications. Two such devices are the punchthrough diode and avalanche open base bipolar transistor which utilise the same basic structure but break down in two different ways. The punchthrough diode is a three-region structure termed an open base structure where the doping levels are optimised for punchthrough breakdown. The punchthrough diode exhibits low leakage characteristics but suffers from high conductivity modulated resistance at high current levels. This effect is due to the space charge limited effect where the field in the depletion layer is determined by the injected carriers. Once the injected carrier density n=J/qvₛ becomes greater than the ionized acceptors in the base of the punchthrough diode N_{b}, the Poisson equation becomes:

dε/dx=ρ/es=(q/es)(N_{b}+J/qvₛ)=J/eₛvₛ (1)

And integrating twice yields:

J=qvsN_{b}(V/V_{fb}) (2)

Therefore, once conductivity modulation or a space charge effect occurs, the current is expected to be linearly dependent on the voltage.

The open-base bipolar transistor has the same generic three-region structure as the punchthrough diode but the doping levels are optimised for avalanche breakdown and not punchthrough breakdown. Such open base bipolar diodes exhibit low leakage also, but suffer from a large negative resistance region at low current levels which may induce significant instability in the device. However, the positive resistance associated with open base bipolar devices at higher current levels is significantly less than for punchthrough devices due to the exponential dependence of multiplication on applied voltage which will be explained later.

It has previously been recognised that such a structure can exhibit both breakdowns. It has been observed in WO2004/075303 that a three region structure designed for punchthrough behaviour can also exhibit negative differential resistance behaviour at higher current behaviour due to avalanche breakdown. This is described as disadvantageous due to instabilities, and the approach was to design such that this negative differential resistance and associated avalanche breakdown did not occur.

U.S. Pat. No. 6,015,999 found that a double-base punchthrough diode showed negative differential resistance behaviour at higher current levels, but the cause of this negative differential resistance was not explained other than stating than a small amount of avalanche carriers may be contributing to this behaviour.

An object of the invention is to optimise I-V characteristics around the clamping voltage. Another object is to provide for simpler manufacture and/or better current capability.

### SUMMARY OF THE INVENTION

The invention provides an open-base semiconductor diode device comprising emitter, base, and collector layers, wherein the layers are configured and doped such that the device has an IV characteristic with:
i. a punchthrough region beginning at a voltage Vₚₜ with positive resistance, followed by, and
ii. an avalanche region including a positive resistance stage beginning with conductivity modulation at V_{crit} and I_{crit} and having a resistance R_{crit},
iii. wherein the values of V_{crit}, I_{crit} and R_{crit} are set according to the layer configuration and doping.

In another aspect, the invention provides a method of manufacturing an open-base semiconductor diode device comprising emitter, base, and collector layers, the method comprising the steps of configuring and doping the layers such that the device has an IV characteristic with:
i. a punchthrough region beginning at a voltage Vₚₜ with positive resistance, followed by, and
ii. an avalanche region including a positive resistance stage beginning with conductivity modulation at V_{crit} and I_{crit} and having a resistance R_{crit},
iii. wherein the values of V_{crit}, I_{crit} and R_{crit} are set according to the layer configuration and doping.

In one embodiment, the layers are configured and doped so that V_{crit} is close to Vₚₜ.

In one embodiment, the doping of the base is set to a level such that injected current level per unit area (J_{crit}) at which the conductivity modulation occurs due to avalanche behaviour is increased.

In one embodiment, the device has a double-base structure, and the width of a lower-doped base region is minimised such that current density J_{crit} at which the conductivity modulation occurs due to avalanche is increased.

In one embodiment, the width of the lower-doped base region satisfies the following approximation:

$${J}_{crit} ∝ \frac{m ( {N}_{b} {W}_{b} + {N}_{b -} {W}_{epi} )}{{f}_{b} {W}_{b} + {f}_{epi} {W}_{epi}}$$

where m, f_{b} and fₑₚᵢ are real numbers, f_{b} and fₑₚᵢ are typically unity, W_{b} is the width of the higher doped base, Wₑₚᵢ is the width of the lower doped base, N_{b} is the doping concentration of the higher doped base region and N_{b-} is the doping concentration of the lower-doped base region

In one embodiment, the device comprises a N-N+ or a P-P+ double-emitter.

In one embodiment, thickness of N− or P− layers is minimised such that the current-carrying capability is maximised and the doping of this layer does not affect the current-carrying capability of the device.

In one embodiment, the width of the N− or P− region satisfies the following approximation:

$${J}_{crit} ∝ \frac{m ( {N}_{b} {W}_{b} )}{{f}_{b} {W}_{b} + {f}_{epi} {W}_{epi}}$$

where m, f_{b} and fₑₚᵢ are real numbers, f_{b} and fₑₚᵢ are typically unity, W_{b} is the width of the base, Wₑₚᵢ is the width of the N− or P− region, N_{b} is the doping concentration of the base region.

In one embodiment, the N− or P− layer doping is sufficiently low such that the N− or P− layer is fully depleted pre-breakdown and the capacitance of the device is minimised.

In one embodiment, wherein the N− or P− layer is sufficiently wide such that, when biased for punchthrough breakdown, it is wider than a depletion region formed in this layer due to the applied bias.

In one embodiment, the N− or P− layer is sufficiently wide such that, when biased for punchthrough breakdown, it is wider than the sum of the manufacturing tolerance of this layer and the depletion region formed in this layer due to the applied bias so that the manufacturing tolerances in Vₚₜ are minimised.

In one embodiment, the N− or P− layer doping is approximately equal to the base doping.

In one embodiment, the device has a bi-directional open base structure with a double-emitter and a double-collector

In one embodiment, boron is chosen for the base and is implanted through a crystalline lattice after the top surface has been implanted and recrystallised to form a layer such that a plateau of boron dopant of nearly constant concentration is achieved to allow good bidirectional behaviour.

### DETAILED DESCRIPTION OF THE INVENTION

The invention will be more clearly understood from the following description of some embodiments thereof, given by way of example only with reference to the accompanying drawings in which:—

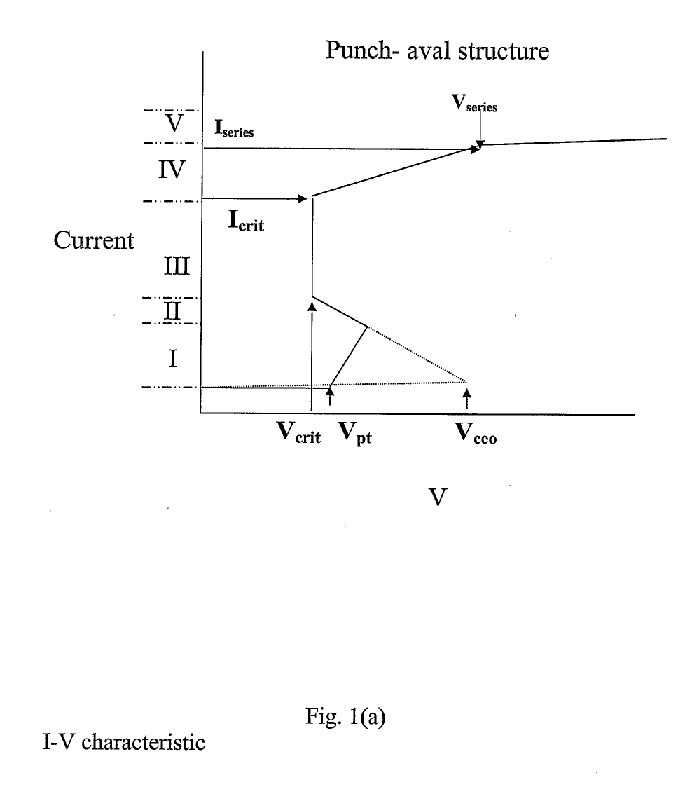

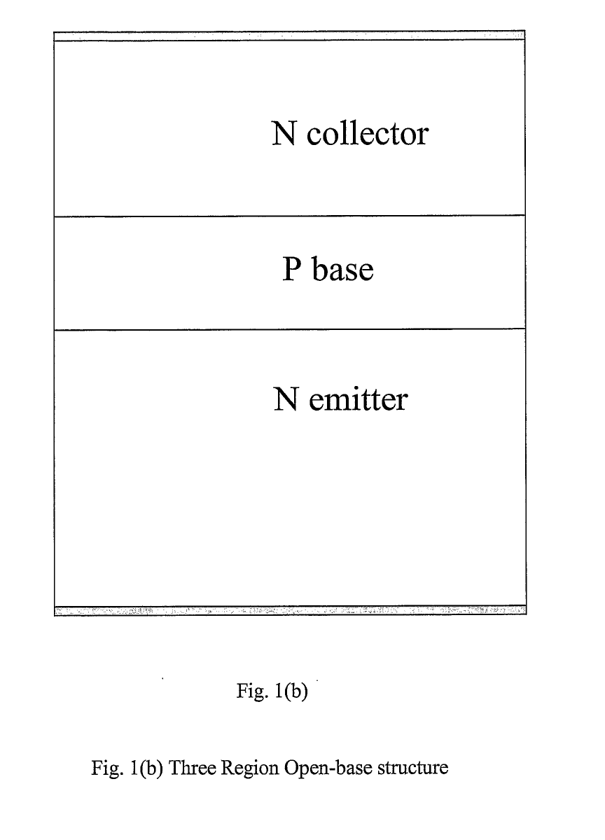

FIG. 1(a) is a diagrammatic representation of the I-V characteristic at breakdown of a three region open base structure of the invention, shown in FIG. 1(b);

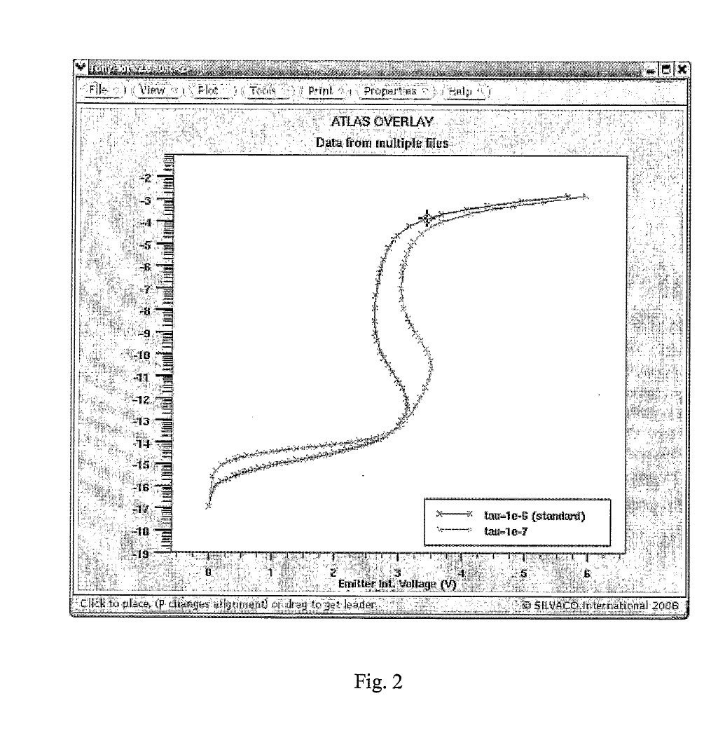

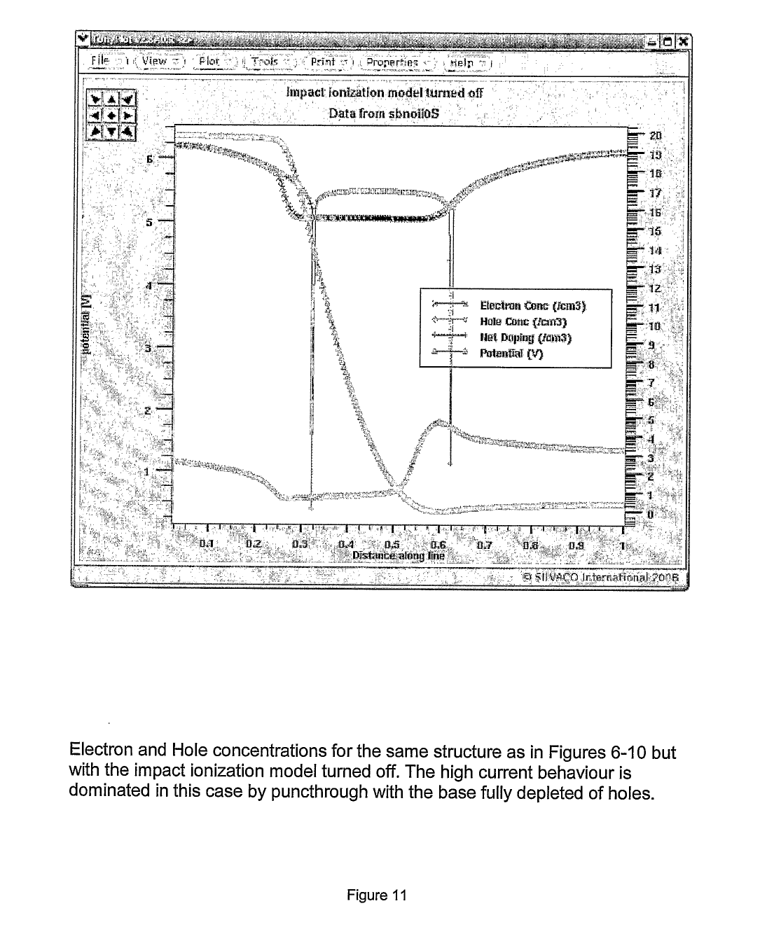

FIGS. 2 to 11 are simulated and measured plots demonstrating performance;

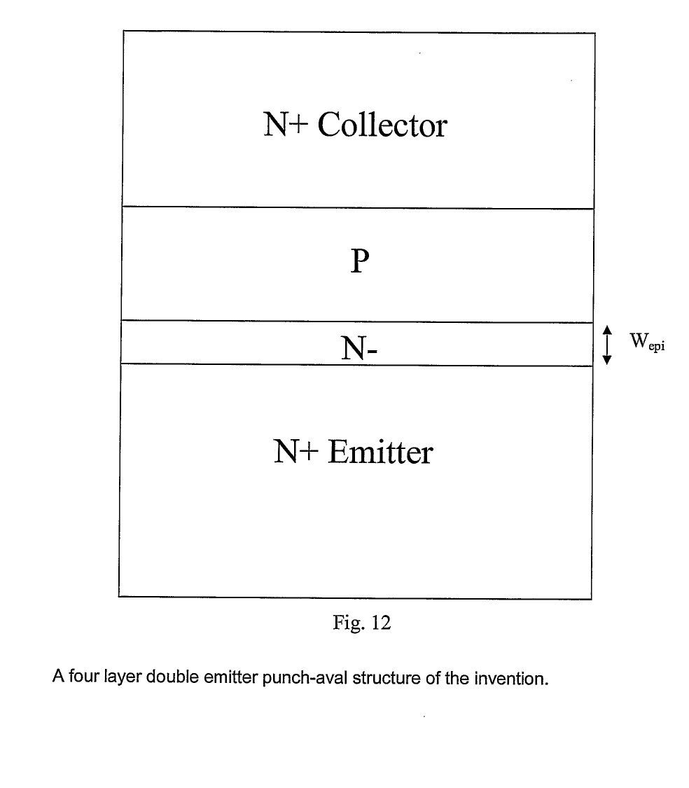

FIG. 12 is a diagram of a four-layer structure of the invention termed a double-emitter structure;

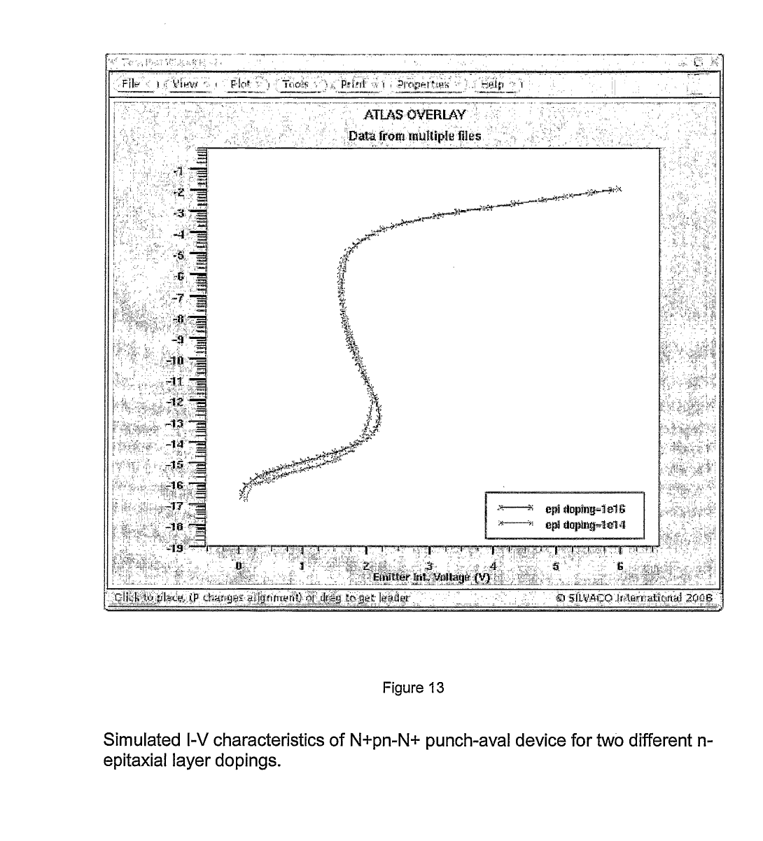

FIGS. 13 to 15 are simulated plots demonstrating performance of the four-layer structure; and

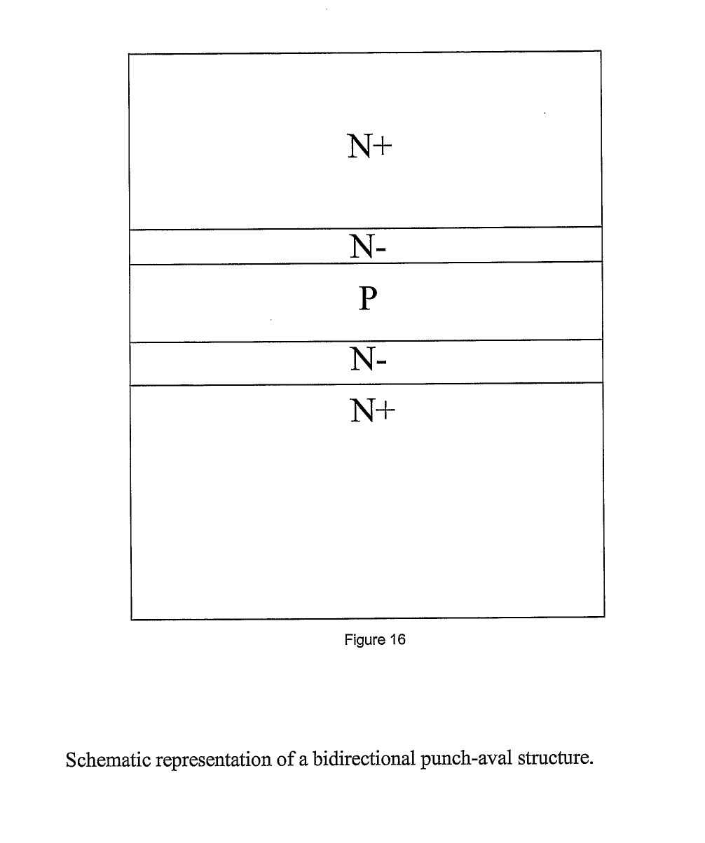

FIG. 16 is a diagram of a bidirectional five-layer structure.

This invention provides a hybrid punchthrough-avalanche device which exhibits low leakage punchthrough breakdown at low current levels followed by avalanche breakdown at higher current levels. In particular, the behaviour of this structure after conductivity modulation occurs is examined and it is shown that this is due to avalanche breakdown even though the applied voltage in this region of operation is higher than the required punchthrough voltage of the structure. This allows further optimisation of the structure such that the area, leakage and capacitance of the structure can be minimised whilst providing maximum current carrying capability.

A three-region open base structure which has a semiconductor region of first conductivity type followed by a semiconductor region of second conductivity type and a third semiconductor region of first conductivity type is provided (as illustrated in FIG. 1(b)) in a first embodiment which has characteristics as shown in FIG. 1(a). The structure has two p-n diodes back to back. There is electrical contact to the top and bottom regions (collector and emitter) and the middle region (base) is floating electrically.

Importantly, there is a region I in the I-V characteristic starting from a voltage Vₚₜ during which the diode behaves as a “punchthrough” diode. For punchthrough characteristics the punchthrough breakover voltage can be approximated,

Vₚₜ=W_{b}²qN_{b}/2εₛ, (3)

Where W_{b} is the width of the base of the device, and N_{b} is the base doping. The Gummel number of the base can be approximated as the product of W_{b} and N_{b}. Hence Vₚₜ is proportional to the base gummel number.

This determines the point at which the depletion region of the top diode (collector-base) reaches or punches through to the bottom diode (base-emitter). The above simple equation assumes that the collector-base depletion region is much larger than the base-emitter depletion region at punchthrough.

The open base bipolar characteristic of the structure is determined by the relation:

(M−1)β=1 (4)

Where M is the avalanche multiplication factor of the collector-base junction and exponentially increases with applied voltage. β is the current gain (I_{c}/I_{b}) of the transistor even if I_{b} cannot be directly measured as there is no base terminal. I_{b} is instead a feedback current in the open-base device.

FIG. 1(a) also shows by dotted lines an avalanche breakdown of the three region structure starting from a voltage BVceo. If the structure were appropriately doped, the voltage would rise to BVceo and then avalanche breakdown would occur. At this voltage the avalanche generated carriers (characterised by M) become significant and beyond which the relation (M−1)β=1 holds true. It is observed that there can be a pronounced negative resistance. This negative resistance characteristic is due to the fact that the gain (β) of the transistor increases with current level until the gain reaches a maximum βmax which is then relatively insensitive to current level until a subsequent positive resistance region occurs, as described in more detail below. As β increases with current level, M must decrease to satisfy the relation (M−1)β=1. M is an increasing function of the collector-base electric field and hence the applied voltage. Therefore, the applied voltage decreases with current level until the condition of βmax is achieved or until conductivity modulation dominates the device behaviour and hence produces the negative resistance characteristic. There is a nearly vertical characteristic over a certain current range once βmax is achieved. This characteristic would be ideal for a clamping device where the current rises vertically with little or no change in operating voltage V_{crit}. However, the initial large negative resistance characteristic (dotted lines) of the open-base characteristic is normally not desirable as it may cause instabilities in the device operation.

The characteristics of FIG. 1(a) have been achieved by doping and region thickness so that punchthrough occurs first at low current levels (i.e. Vpt<BVceo) with a certain positive resistance over a certain current range (Region I) followed by avalanche behaviour with negative resistance over a current range termed Region II and a positive resistance region termed Region III. At higher currents, a positive resistance region (still due to avalanche behaviour) arises due to conductivity modulation starting at a current I_{crit} and a voltage V_{crit} (Region IV). Finally, a series resistance limited positive resistance region (Region V) starts at a current Iₛₑᵣᵢₑₛ and a voltage Vₛₑᵣᵢₑₛ. The positive resistance in Region V is determined by the series resistance of the device which is primarily determined by the resistance of the substrate material.

A negative resistance region as observed in Region II may or may not be desirable as it has the potential to decrease the operating voltage or clamping voltage of the circuit but at the expense of increased instability. It is therefore optional to have a negative resistance region as part of the characteristic during the avalanche phase.

For ideal (vertical) operation, Vₚₜ should occur at or as close to the same voltage (V_{crit}) at which the conductivity modulated positive resistance begins (see FIG. 2). However, V_{crit} occurs at a much higher current level (I_{crit}) than Vₚₜ. The I-V characteristic exhibits a succession of resistances due to punchthrough (Region I) followed by negative and/or positive resistances (Region II and Region III) due to avalanche before I_{crit} is reached The negative resistance region of Region II occurs if the punchthrough characteristic of Region I transforms into the avalanche characteristic at current levels where D is less than βmax. The negative resistance characteristic will dominate for increasing current until βmax is reached (Region III) or I_{crit} is reached (Region IV). For some applications, negative resistance should be minimised as it may introduce instabilities into the circuit.

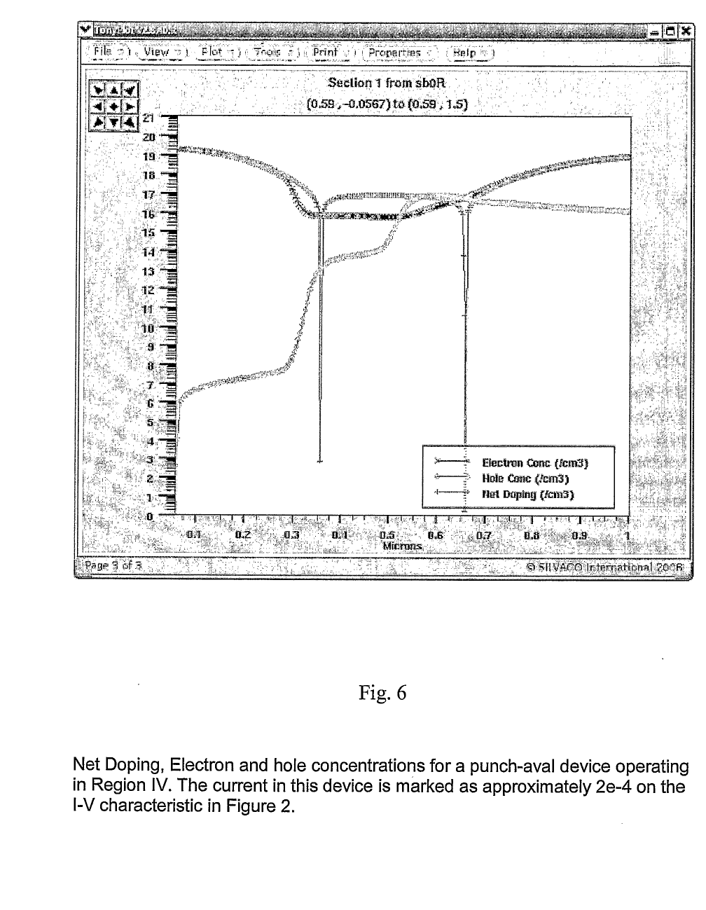

It is therefore sometimes advantageous to reduce the current level at which the relation (M−1)βmax=1 holds true so as to minimise the operation region where negative resistance dominates the device (region II). This can be achieved through the understanding that β is an increasing function of current level due to recombination effects in the base-emitter junction. Recombination in the base-emitter junction reduces β and thus this should be minimised. By increasing the base-emitter recombination lifetime, the current level at which βmax is achieved can be dramatically reduced. FIG. 2 shows this phenomenon as a function of minority carrier lifetime. It shows the design of the I-V characteristic by modifying the minority carrier lifetime tau (τ) from 1e-6 (standard) to 1e-7. The operating point at approximately 1e-4 current is marked for FIG. 6. The device area for all simulations in this document is 1 μm2. The minority carrier lifetime (τ) can be increased by reducing the number of defects in the junction. It is to be noted that the value of βmax itself is also increased by increasing the carrier lifetime so that there is a decrease in the voltage at which it occurs in order to satisfy the relation (M−1)β=1.

The equation which describes the recombination current in the depletion region is:

I_{rd}=Iᵣexp(qV_{be}/2 kT) (5)

where Iᵣ=qW_{d}nᵢ/2τ

It is clear from the equation above and the numerical simulations that this current can be reduced by increasing τ. The β value reaches βmax at a much lower current level once the recombination in the depletion regions is reduced. This reduction in recombination current in the base emitter region can also be accomplished by reducing the doping concentrations at this junction as this inherently reduces the number of recombination centres (defects) across the bandgap.

One way to increase the current carrying capability of a device for a specified voltage range, is to reduce V_{crit} in relation to Vₚₜ. However, this adds instabilities into the operation of the device when used as an over-voltage or over-current protection device. Therefore, this design trade-off will be application-specific. For Vₚₜ to be designed to be equal to V_{crit} requires design of the collector, base and emitter region.

Vₚₜ can be broadly designed as per the equations above whereas the relation (M−1)β=1 which defines V_{crit} should be designed using numerical simulation with appropriate doping and defect profiles and advanced impact ionization models as these values are very dependent on concentration and defect gradients and cannot be simply formulated.

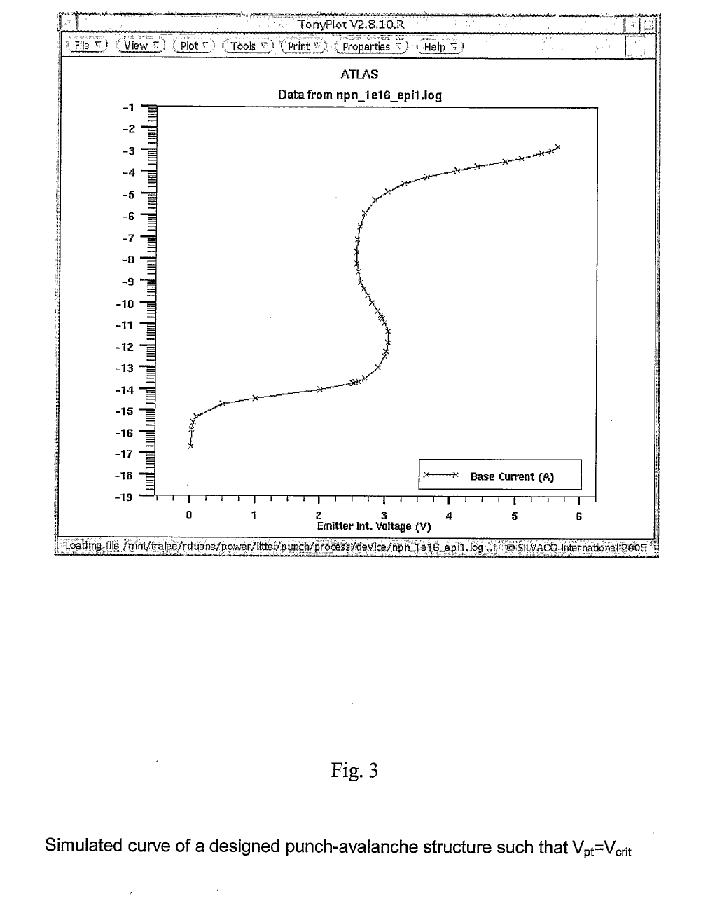

However, to help with the design process, the first two parameters that require designing is the base doping and base width. This combination of base doping and base width sets to a large degree the punchthrough voltage as described. However, these doping concentrations and widths also determine the M and the β values. The M value is determined by the collector and base doping levels and the doping level gradient at the junction between the two regions. The β value as a function of current is largely determined by the emitter and base doping levels, the base width and the minority carrier lifetime. Therefore, it can be seen that in order to achieve the design criteria, the base doping and width are the most important criteria. The collector and emitter dopings are largely chosen to limit on resistance and as such are chosen to be highly doped >1e19 but not so highly doped so that significant band gap narrowing occurs and reduces gain (for the emitter case). For Vₚₜ=3V, a base doping in region of 5e16 to 1e17 and a base width of 0.3 microns is required to achieve a value of V_{crit} which is close to Vₚₜ. FIG. 3 shows the numerically simulated characteristic of an open base structure for Vₚₜ=2.8V. In this numerical simulation, the base doping concentration is 1e17/cm3 and the base width is 0.3 microns.

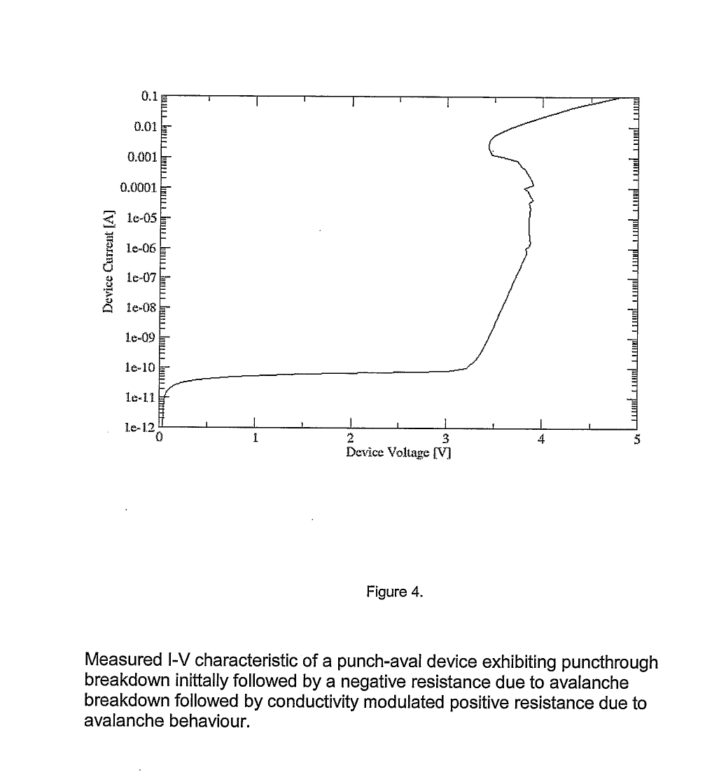

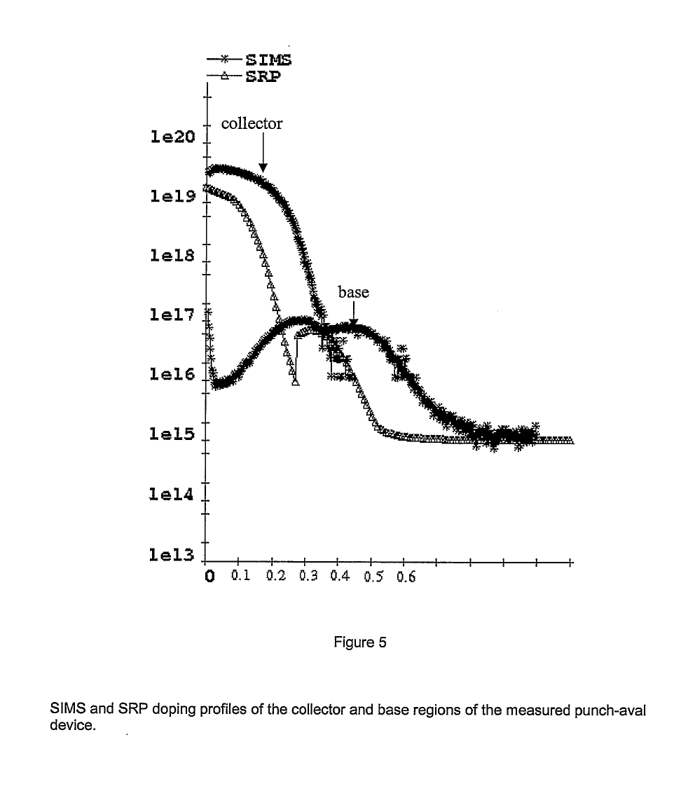

FIG. 4 shows a measured result for a punch-aval device operating at 3.3V as described later in this document. The SIMS and SRP of the collector and base dopings of the device are shown in FIG. 5 and described in more detail below.

In all cases, PNP type diodes can also be used.

An equation which describes the I-V characteristic in FIG. 1 is as follows:

V_{c}=Vₛₑᵣᵢₑₛ+(I_{c})Rₛₑᵣᵢₑₛ

V_{c}=V_{crit}+(Iₛₑᵣᵢₑₛ−I_{crit})R_{crit}+(I_{c})Rₛₑᵣᵢₑₛ (6)

where R_{crit} is an increasing function of current density J, I_{crit}=J_{crit}A and Rₛₑᵣᵢₑₛ=ρt_{sub}/A where t_{sub} is the thickness of the substrate, ρ is the resistivity of the substrate and A is the area of the device. V_{crit} is constrained by application to be within a certain voltage of Vₚₜ.

The capacitance of the structure pre-breakdown is also important for a number of applications and this can be described as follows

$$C = \frac{{C}_{bc} * {C}_{be}}{{C}_{bc} + {C}_{be}} \approx ɛ \frac{A}{{d}_{bc} + {d}_{be}} \qquad ( 7 )$$

Where bc is the base-collector junction and be is the base emitter junction and d is the depletion width of the junctions pre breakdown. d_{bc} is comprised of a base depletion width (d_{b}^{c}) and collector depletion width (d_{c}^{b}) due to applied bias across the base-collector junction. d_{be} is comprised of a base depletion width (d_{b}^{e}) and emitter depletion width (dₑ^{b}) due to applied bias across emitter-base junction. Note that pre-breakdown, the majority of the voltage is dropped across the reverse biased base-collector junction whereas there is approximately 0.4-0.6V inbuilt voltage in the slightly forward biased base-emitter junction.

For overcurrent protection applications, the voltage seen by the protected circuit (V_{c}) should be minimised, the capacitance of the device is required to be below a certain value (dependent on application) and the area and hence cost of the device must always be minimised. The absolute minimum possible area of the device is limited by the series resistance requirement of the application as there is a minimum resistivity and thickness of substrate available from substrate suppliers. As can be observed, simply decreasing the area of the device to the series resistance limit does result in a decrease in cost and capacitance but at the expense of a decrease in I_{crit} and an increase in R_{crit} which results in a significant increase in applied (clamping) voltage V_{c}. As V_{crit} is set by application, the key parameters of the device which can be optimised are J_{crit} and R_{crit}.

### High Current Behaviour

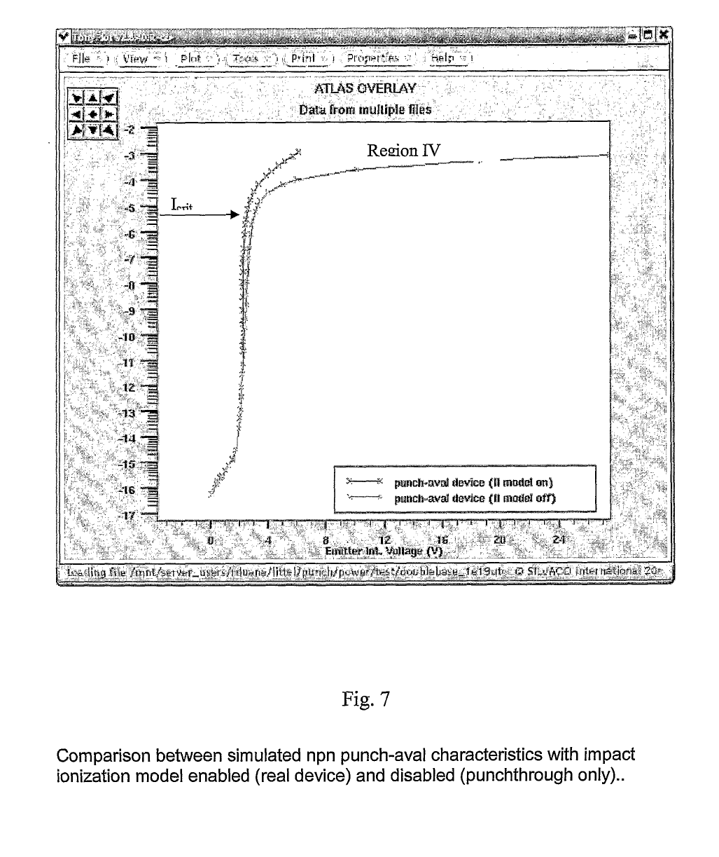

The issue of high current behaviour (Region IV) characterised by J_{crit} and R_{crit} of the hybrid punch-aval device has been understood and optimised in the invention. We demonstrate that even though the hybrid punchthrough-avalanche device can, according to theory, be controlled by either avalanche or punchthrough mechanism during conductivity modulation (Region IV), the avalanche mechanism dominates. We recognize that J_{crit} and R_{crit} are important parameters and they are optimised for this hybrid punch-aval structure. From extensive analysis and simulations shown in FIGS. 6-11, it is clear that Region IV is dominated by the conductivity modulated avalanche breakdown and not due to punchthrough of the back-to-back diodes. It can be seen in FIG. 6 that for very high current densities as observed in Region IV, the base is not fully depleted of hole carriers as in the case of a punchthrough structure but instead is governed by the avalanche feedback (M−1)β=1 mechanism. The series resistance of this structure is insignificant at these current levels such that the observations are valid for Region IV. It is important to note that even though the applied voltage can, in theory, be much higher than the punchthrough breakover voltage Vₚₜ in region IV, the structure operates as an open base bipolar structure with a much smaller positive resistance than if punchthrough behaviour dominated in this region. FIG. 7 compares two simulated curves for the same npn structure. One curve represents the real physical device (punch-aval structure) with impact ionization enabled and the other curve represents an identical structure with the impact ionization model in the simulator disabled (such that the device is governed by the punchthrough mechanism only). This comparison highlights the advantage of the high current mechanism of the avalanche behaviour in the punch-aval device. The device with the impact ionization model disabled exhibits a linear current versus voltage behaviour in Region IV which agrees with purely punchthrough behaviour. Meanwhile the hybrid punch-aval characteristic with the impact ionization model included shows a much improved positive resistance characteristic in Region IV. This is due to the nature of the breakdown mechanism which is determined by the (M−1)β=1 relation and is described next. For both of these curves, the series resistance of the structure was not a factor for the current ranges chosen and thus Region V characteristics were not observed.

From this understanding and subsequent simulations, the onset of this second positive region has been determined to be caused by the high level injection effect or conductivity modulation of the avalanche mechanism. At the transition between Region III and Region IV defined by V_{crit} and I_{crit} or J_{crit}, injected electron (for NPN) carriers due to the flowing current reach the same level as the background base doping at the base-emitter junction. Charge neutrality means that the number of holes in the quasi neutral base region (for NPN device) must increase. This increases the base gummel number (and associated majority carrier mobile base charge) which in turn reduces the current gain (β) of the device. This reduction in β means that the M factor must increase to satisfy the relation (M−1)β=1. The M factor is largely determined by the collector-base electric field and thus the collector-base voltage must increase and the overall applied voltage increases. However, unlike the conductivity modulation or space charge limited effect of the punchthrough structure, the M factor is exponentially dependent on the collector-base electric field (collector-base voltage) and hence the applied voltage. Therefore, the current has a much larger dependence on the applied voltage also. FIG. 7 shows this explicitly whereby the punchthrough device has a linear current dependence on voltage in Region IV whereas the hybrid punch-avalanche device approximates a power law dependence on voltage. This means that the combined punch-avalanche structure has inherently lower positive resistance characteristic (R_{crit}) than the equivalent punchthrough structure. It is also noted that R_{crit} is a decreasing function of current density for both structures.

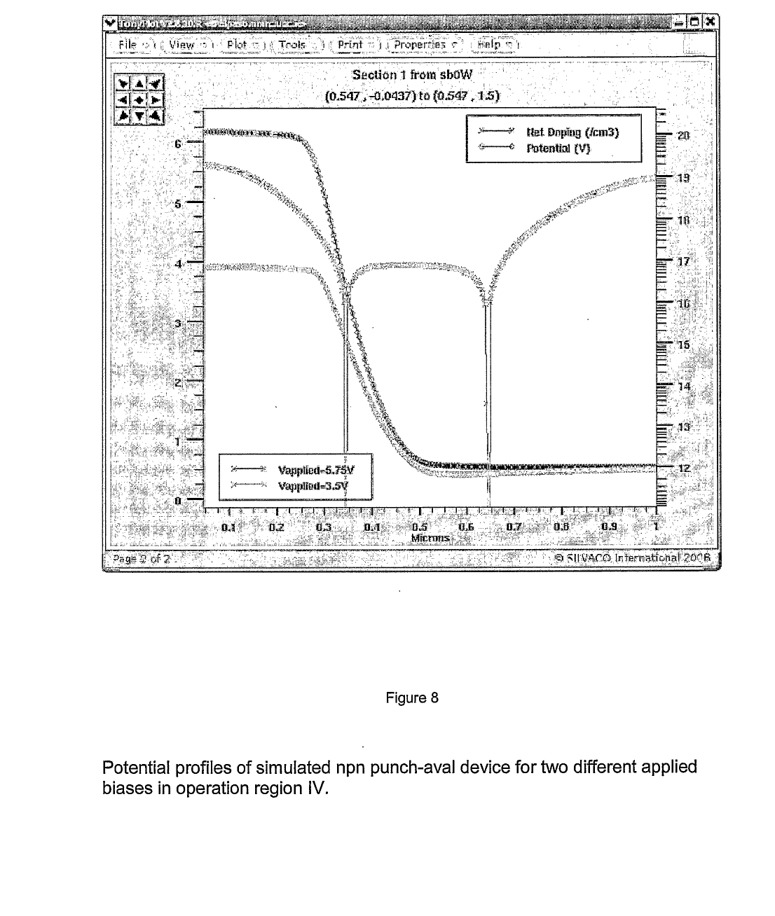

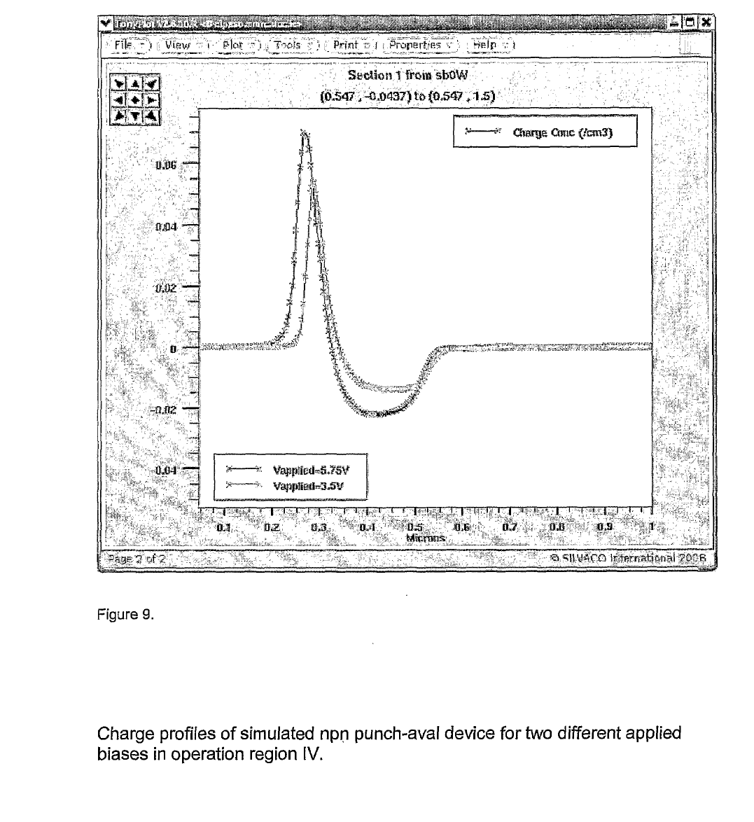

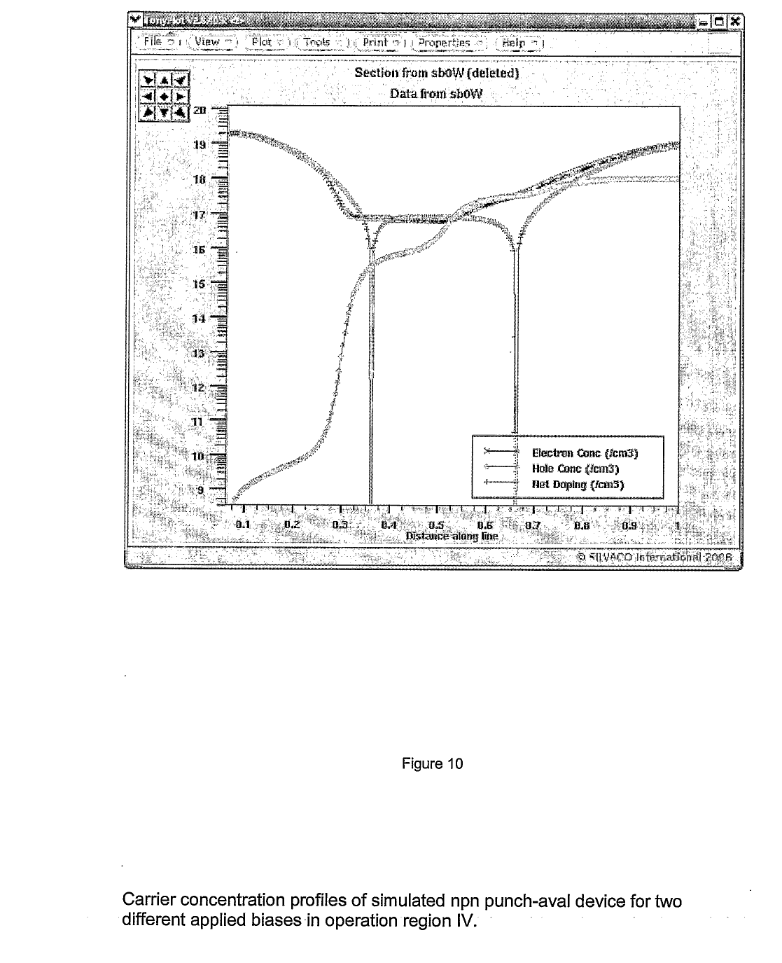

The fact that the final punchthrough voltage (defined as the voltage at which the collector-base junction depletion width has totally punched through to the base-emitter depletion width) of the punch-aval structure has been exceeded in this positive region (IV) is analysed. From such a theory, it is expected that a punchthrough mechanism would dominate the behaviour. From simulations, it is shown that the inbuilt base-emitter voltage at these current levels has largely disappeared. This is due to the avalanche feedback mechanism of the open-base bipolar structure whereby the avalanche-generated feedback hole current (for npn devices) controls the emitter-base potential. Therefore, the final punchthrough voltage is slightly higher (less than 0.7V) at larger current densities for this structure as the emitter-base depletion region is smaller. For currents in Region IV (i.e. where series resistance is not a factor) where the applied voltage increases such that expected final punchthrough voltage is exceeded, the punchthrough mechanism is expected to dominate. However, from simulations, as can be seen by FIG. 8 and FIG. 9, the increase in reverse bias across the collector-base junction results in an increase in depletion width to the collector side only. The increased voltage requires increased charge on both sides of the junction as seen in FIG. 9. On the collector side, this increased positive charge is realised by an increase in the depletion of the emitter quasi neutral region. On the base side of the base-collector junction, the injected electron carriers are higher than the hole carriers as shown in FIG. 10. These excess electron carriers provide the extra negative charge required on the base side without the need for increasing the depletion width on the base side. Therefore, there is no punchthrough of the collector-base junction to the base-emitter junction. The structure is still operating as an open-base bipolar with multiplication of holes at the collector-base junction driving the diffusion of holes across the emitter base junction which in turn drives the electron current.

For overcurrent or overvoltage applications, it is also clear from Equation (6) that the onset of this positive resistance region (due to conductivity modulation of the avalanche behaviour) should be avoided or at least delayed to a higher current density level (J_{crit}) as it causes the applied voltage across the device and also the circuit (V_{c}) it is protecting to increase.

In order to do this, the doping in the base of the device must be increased such that the injected current density (J_{crit}) at which it occurs also increases. From simulations, it is clear that the higher base doping provides a more desirable characteristic at high current levels. From simulations, increasing the base doping results in an approximately linear increase in J_{crit}

In the case of relatively uniform base doping, the capacitance and leakage current per unit area increases with base doping as well as the current per unit area (J_{crit}). However, these important parameters do not increase as strongly with base doping. The base gummel number and mobile base charge are modified by the injected carrier density which is proportional to the current density. In the case of NPN devices, the injected electron carrier concentration induces a corresponding increase in injected hole concentration (p) in the quasi-neutral base to maintain charge neutrality. In addition, the impact ionization of holes at the base-collector junction contributes to the injected hole density p. The total majority carrier mobile base charge (Q_{b}) due to base impurities (N_{b}) and due to high level injection (p) can be approximated as follows

Q_{b}=Q_{base}+Q_{injec}=q(p_{b}+p)W_{b}C/cm2. (8)

where Q_{base} is the majority carrier mobile base charge at low injection levels, Q_{injec} is the additional majority carrier mobile base charge due to injected carriers, p_{b} is the hole concentration in the base due to doping and which is linearly dependent to the base doping (N_{b}) and W_{b} is the width of the base region. By defining Q_{injec}^{crit} as the level of injected base charge which increases Q_{b} by a factor mQ_{base} (i.e. Q_{b}=Q_{base}(1+m)) such that significant conductivity modulation of the current-voltage characteristic occurs, J_{crit} which is linearly proportional the injected carrier density p_{crit} can be approximated as follows,

J_{crit}∝m×N_{b} (9)

Where m is a real number.

The depletion width of the base portion of both the collector-base depletion width (d_{b}^{c}) and the emitter-base depletion width (d_{b}^{e}) increases approximately as the square root of the base doping for the case of uniform base doping.

The leakage current per unit area which is primarily determined by the generation current in the collector-base junction should not increase strongly as generation lifetime is not a function of dopant density at the collector-base junction, rather defect density. However, if the base doping at the collector junction is increased to the band-to-band tunneling regime (approximately 1e18), then the leakage current will increase drastically due to band-to-band tunneling. Therefore, this should be avoided and sets an upper limit on the minimum base doping.

According to equations (7), (8) and (9), for uniformly doped bases, increasing the base doping results in a linear increase in J_{crit} whereas the capacitance per unit area and leakage per unit area increase sub-linearly. These equations have been confirmed by numerical simulation results. Therefore, the first design criteria is to increase the base doping as this allows a corresponding reduction in the required area of the device (for the same I_{crit}=J_{crit}A) which also results in a net reduction in the capacitance and leakage of the device. The ultimate limit for increasing the base doping is that significant band to band tunneling should not occur in the base-collector region which would drastically increase the device leakage. A more practical limit is that the punchthrough voltage of the device is also determined by the product of the width and the doping of the base region (Gummel number). Therefore, increasing the doping requires a reduction in the width of the base for the same punchthrough voltage which may be difficult to fabricate in a manufacturable way. The ultimate limit for reducing the area of the device is set by the series resistance requirement.

In all cases, PNP type diodes can also be used.

### Punchthrough Manufacturability

A problem with all punchthrough diodes including the hybrid punchthrough-avalanche structure described above is manufacturability due to variations in epi thickness and dopant level. FIG. 12 shows a structure which overcomes this problem.

The manufacturability of this device is superior to the standard singlebase device and also of prior doublebase structures. The movement of the top junction to the bottom junction constitutes punchthrough of the device. It is typical practice to grow epitaxial layers on top of the emitter substrate to provide for the base and collector regions. Variations in grown epitaxial layers in terms of thickness (Wₑₚᵢ^{grown}) and doping cause problems in the variation of the punchthrough voltage when the epitaxial layer is utilised as a base. In particular, thicker layers of lower base doping provide better manufacturability but at reduced performance due to the onset of high current effects at lower current levels as described above.

One approach to this problem is the implantation of the base doping by providing a controllable doping and thickness. However, the base is commonly implanted into a grown epitaxial layer on top of the emitter substrate whose thickness (Wₑₚᵢ^{grown}) varies across the wafer. In the case of a p− epitaxial layer, on which a p+ layer has been implanted to provide the highly doped portion of the base so as to provide two distinct base layers (known as a double-base structure), the width of the p− layer will exhibit variations across the wafer at the emitter junction. This will cause punchthrough variations as this p− layer contributes to the effective base doping and thickness and hence to the punchthrough voltage. Therefore, a 4 layer structure is provided which shows improved manufacturability as shown in FIG. 12. The n− layer is preferably grown through epitaxy and is implanted to provide a p base and n+ collector. This device can be termed a double-emitter structure. The resulting n− region width after boron implant (Wₙ₋) can be chosen to be greater than the tolerance of the epitaxial layer thickness and additionally sufficiently wide such that the depletion region in this layer caused by the forward biasing of emitter-base diode upon application of bias is totally encompassed by this layer across the whole wafer. As the punchthrough voltage of the structure is determined by the combined width of the base, collector-base depletion thickness and emitter-base depletion thickness, this design criteria ensures that any variations in the epitaxial layer width do not cause any variations in the emitter-base depletion thickness and hence punchthrough voltage. Therefore, the width of this layer (Wₙ₋) should be designed such that it is larger than the sum of the manufacturing tolerance of the growth of this layer and the depletion region width caused by the forward biasing of the emitter-base regions pre punchthrough breakdown.

In all cases, PNP type diodes can also be used.

### High Current Behaviour of Double Emitter and Double-Base Devices

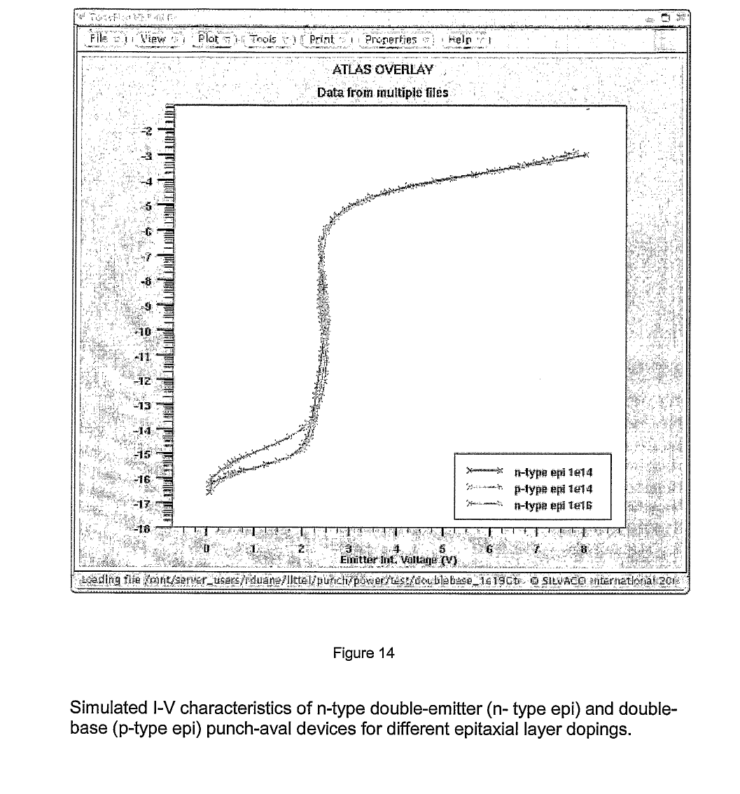

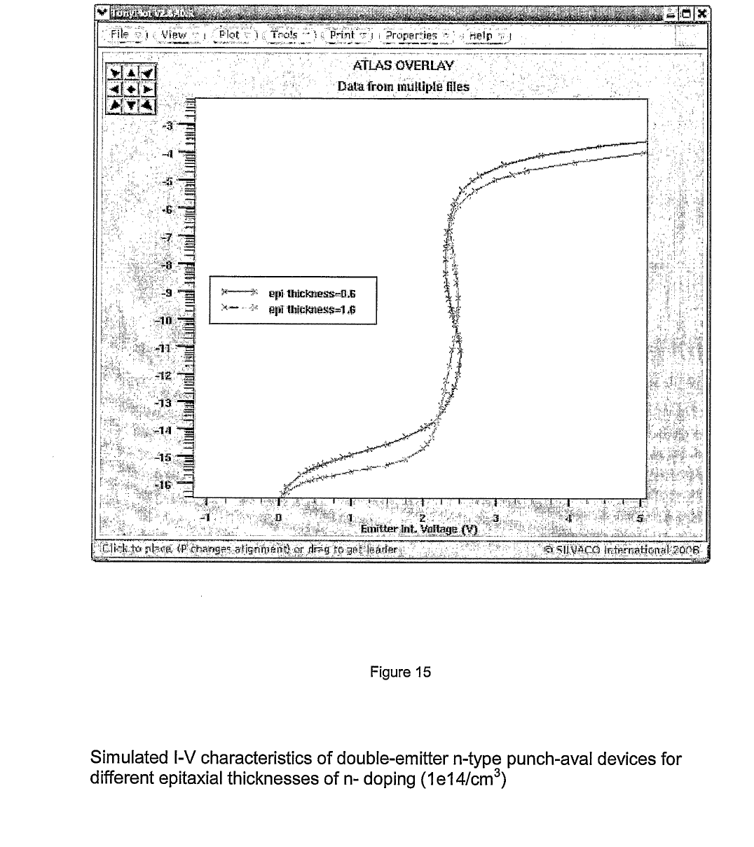

For structures of the type N+pn-n+ (shown in FIG. 12), termed double-emitter structures, a new effect is observed to improve the high current behaviour. Once such a structure exhibits high current levels, the injected majority carriers (electrons) in the n− layer cause a corresponding increase in the holes in the region to maintain charge neutrality. This increase in hole concentration effectively increases the base width and base charge such that β is reduced. Therefore, this n− layer primarily determines the point at which the positive resistance region IV begins to occur or J_{crit}. It is also observed that the doping of the n− layer is not a factor in the high current behaviour (FIG. 13). The doping that does matter for this effect is the base doping. An interesting point is that identical high current behaviour can be achieved if the dopant is p type (double-base where there are two distinct base doping regions N+pp-N+) or n type (double-emitter) for low p− and n− dopings as shown in FIG. 14. This signifies that the n− epitaxial layer can be considered to be acting as an extension of the base at high injection levels. However, for increased doping of the p− layer in double-base structures the high current behaviour is affected as it contributes to the base charge. Only the width of the n− layer is important for the N+pn-N+ structure. The effect can be explained with reference to the base charge. It is the positive charge in the n− layer with respect to the overall base charge that defines the high current behaviour. Therefore, the important variables are the n− layer width, hole concentration in the n-layer and the hole concentration and width of the base layer. The larger the n− layer width, the larger the effect of the n− layer on total base gummel number and total majority carrier mobile base charge (Q_{b}) at lower current levels J_{crit} (lower injected hole concentrations) as observed in FIG. 15 and can be approximated as follows:

Q_{b}=Q_{base}+Q_{injec}=q((p_{b}+p)W_{b}+Wₙ₋p1)C/cm2 (10)

where p_{b} is the hole concentration in the base layer due to the base doping (N_{b}), p is the hole concentration in the base layer due to carrier injection (charge neutrality and impact ionization) and p1 is the hole concentration in the n− layer due to carrier injection (charge neutrality and impact ionization). It can be observed from this equation that the n− doping level does not matter in this case. In the case of a p− layer (as in double base structures), the p− doping (N_{b-}) does contribute to the low level injection base gummel number (and hence punchthrough voltage from equation (1)) and majority carrier mobile base charge Q_{base} through

Q_{b}=Q_{base}+Q_{injec}=q((p_{b}+p)W_{b}+Wₚ₋(p_{b1}+p1))C/cm2. (11)

Where p_{b1} is the hole concentration in the p− layer of width Wₚ₋ due to the p-doping N_{b-}.

By defining Q_{injec}^{crit} as the level of injected base charge which increases majority carrier mobile charge density Q_{b} by a nominal factor mQ_{base} (i.e. Q_{b}=Q_{base}(1+m)) such that significant conductivity modulation occurs, there is an inverse relationship between J_{crit} (linearly proportional to p_{crit} and p1_{crit}) and epitaxial width defined as Wₑₚᵢ=Wₙ₋(double-emitter)=Wₚ₋(double-base) which can be approximated as follows:

$${J}_{crit} ∝ \frac{m ( {N}_{b} {W}_{b} + {N}_{b -} {W}_{epi} )}{{W}_{b} + {W}_{epi}} \qquad ( 12 )$$

Where W_{b} is the width of the base (double-emitter) or the width of the higher doped portion of the base (double-base). N_{b-} is zero for the case of a singlebase, double-emitter structure. For the uncommon case of a doublebase doubleemitter structure, Wₑₚᵢ in the denominator is the sum of the widths of the low doped portion of the base and the low doped portion of the emitter.

In the case of double-base structures, increasing the doping in the low doped epitaxial layer does marginally contribute to the base gummel number but in practical devices, the major contribution is from the higher doped portion of the base. In addition, it is not possible to significantly increase the base gummel number as this also largely determines the punchthrough voltage (Vₚₜ) of the device. Therefore, for both double-base and double-emitter structures, the critical current density for conductivity modulation to take place (J_{crit}) is inversely proportional to the epitaxial width (Wₑₚᵢ) as defined above. Note that it is assumed that the injected carrier concentration is relatively constant over the entire base and low doped emitter region i.e. p_{crit} is approximately equal to p_{crit1}. In the case of significant non-uniformity in the injected carrier concentrations, there would be additional weighting factors for W_{b} (represented by the term f_{b}) and Wₑₚᵢ (represented by the term fₑₚᵢ) in the denominator of equation 12 as follows:

$${J}_{crit} ∝ \frac{m ( {N}_{b} {W}_{b} + {N}_{b -} {W}_{epi} )}{{f}_{b} {W}_{b} + {f}_{epi} {W}_{epi}} \qquad ( 12 a )$$

where m, f_{b} and fₑₚᵢ are real numbers and f_{b} and fₑₚᵢ are typically unity.

In addition, the positive resistance in Region IV (R_{crit}) which is a function of current density is also reduced by increasing Wₑₚᵢ. This is because the base gummel number and majority carrier mobile base charge increases more strongly with device current density J_{crit} (proportional to the injected hole concentrations p and p1) if the epitaxial thickness is larger as outlined above. This results in a larger increase in β with current density which necessarily results in a larger increase in (M−1) with current density to maintain the avalanche breakdown condition. The larger increase in (M−1) is achieved by a larger increase in the collector-base voltage and hence applied voltage. The net result is a larger increase in applied voltage as a function of current (R_{crit}) in Region IV.

For the common case of epitaxial layer grown on highly doped substrate (emitter), it is noted that the thickness of the transition region between highly doped substrate and lower doped grown epitaxial layer will also contribute to the effective base gummel number (majority carrier mobile base charge) at high injection levels. This is because the effective base-emitter junction moves from the base-epitaxial layer metallurgical junction to the metallurgical epitaxial layer-substrate junction at higher currents. Therefore, a significant portion of the transition region can be considered to be part of Wₑₚᵢ in the calculations above. Again, in this case, the doping level in the transition layer does not matter, merely the width.

Therefore, from the theory outlined above, it can be observed that J_{crit} and R_{crit} are inversely proportional to Wₑₚᵢ. These equations have been confirmed by numerical simulation results.

Assuming that the epitaxial layer is fully depleted pre-breakdown by choosing a sufficiently low epitaxial doping, the capacitance is also inversely proportional to the epitaxial width according to equation (2) as it determines the emitter portion (dₑ^{b}) of the base emitter depletion thickness in the case of n− epitaxy for double-emitter NPN devices (base portion (d_{b}^{e}) of the base emitter thickness in the case of p− epi for double-base NPN devices).

$$C \approx ɛ \frac{A}{{d}_{bc} + {d}_{be}} \qquad ( 13 )$$

As the depletion width of the base portion of the base-collector junction (d_{b}^{c}) is at the point of punch-through with the depletion width of the base portion of the base-emitter junction (d_{b}^{e}) pre-breakdown, the pre-breakdown capacitance can be approximated:

$$C \approx ɛ \frac{A}{{d}_{b}^{c} + {W}_{b}^{total} + {d}_{e}^{b}} \qquad ( 14 )$$

Where W_{b}^{total} is the total base width and can be approximated as the sum of d_{b}^{c} and d_{b}^{e}

From the analytical calculations above and confirmed by numerical simulations, the capacitance per unit area decreases less strongly with Wₑₚᵢ=Wₙ₋(dₑ^{b}) than J_{crit} for the case of double-emitter structures. For the case of a double-base structure, Wₚ₋ is a significant portion of W_{b}^{total}=Wₚ₋+W_{b} and similar dependence of capacitance per unit area on the epitaxial width (Wₑₚᵢ=Wₚ₋) is observed as for the double-emitter structure.

Therefore, the second design criteria to reduce area and cost of either the double-emitter or the double-base device is to decrease the epitaxial width Wₑₚᵢ (including the transition region from highly doped emitter substrate to epitaxial doping) as much as possible. This results in an increase in J_{crit} and R_{crit} which allows a corresponding reduction in area of the device for specified I_{crit}, R_{crit}. As the capacitance per unit area is less dependent on Wₑₚᵢ than J_{crit}, the reduction in area of the device will result in a net decrease in capacitance of the device in comparison with a device with a larger epitaxial width. In addition, the epitaxial doping (not including the transition region) should be low enough such that the n− layer or p− layer is fully depleted pre-breakdown so that the capacitance per unit area of the device is minimised.

The limits for this minimisation will be manufacturability of the epitaxial layer and associated punchthrough manufacturability as described above. Grown Epitaxial thickness (Wₑₚᵢ^{grown}) tolerances of +/−4 percent are achievable at present. Again, the ultimate limit for the area reduction is that Rₛₑᵣᵢₑₛ is acceptable for the application.

In addition, the lowly doped emitter base structure will give an excellent minority carrier lifetime in comparison with a highly doped emitter-low doped base junction thus minimising the negative resistance in the open base structure. This excellent minority carrier lifetime model assumes that the defects generated by the high dose and energy implants for the top region are removed through subsequent annealing steps as these defects would decrease the lifetime. It may also be worthwhile to grow epitaxial silicon in stages to produce the device as in this case the defects are greatly reduced.

In all cases, PNP type diodes can also be used.

### Design for Manufacturability and High Current Behaviour of Double-Emitter and Double-Base Structures

Therefore, the condition for high level injection for double-emitter structures as described above (minimum Wₙ₋=Wₑₚᵢ) needs to be counterbalanced by the constraint for design for punchthrough manufacturability (application-specific) which requires a certain thickness of grown epitaxial layer (Wₑₚᵢ). One resulting design approach is that the doping of this epitaxial layer should be maximised to reduce the depletion width in the layer and hence minimise the required thickness of the layer for improved manufacturability as described above.

By maximising the epi-layer doping in comparison with an equivalent thickness of a lower doped epi-doping layer will result in a capacitance per unit area increase which also must be factored into the design for the application. In essence, assuming a certain minimal n− thickness (Wₙ₋=Wₑₚᵢ), capacitance per unit area is sacrificed by increasing the epitaxial doping to ensure acceptable punchthrough manufacturability for the application. Depending on the punchthrough voltage tolerances that are required by application, the n− layer width and doping can be appropriately chosen. For the 3V application designed in this invention, the width of the n− layer Wₑₚᵢ (after implantation of collector and base regions) of doping level 1e16/cm³ was calculated to be 0.2 microns due to depletion width of applied bias pre-breakdown+0.04 microns (four percent of 1 micron grown epitaxial width (Wₑₚᵢ^{grown}) due to manufacturability variations) resulting in a Wₑₚᵢ (after implantation of collector and base) of 0.24 microns. The addition of the thickness of the transition layer means that Wₑₚᵢ was designed to approximately 0.45 microns to ensure excellent punchthrough manufacturability whilst maximising current carrying capability. To reduce this epitaxial thickness further requires increasing the epitaxial doping to approximately 1e17/cm³ thus resulting in a depletion width of 0.08 microns and Wₑₚᵢ (after implantation of base and collector) of less than 0.3 microns. It is important to note that if the base and collector are to be implanted into a grown epitaxial layer, the epitaxial doping cannot exceed the implanted base doping. In order to decrease the epitaxial width further would require a decrease in the width of the transition region which is a function of the epitaxial growth.

In comparison to the double-emitter structure described above, the p− layer in double-base structure contributes to the punchthrough voltage. Therefore, the punchthrough variation due to epitaxial variations cannot be overcome which make such structures less attractive for punch-avalanche devices. However, disregarding punchthrough variability considerations, for good high-level injection behaviour, the p− layer width (Wₚ₋=Wₑₚᵢ) should be minimised. Decreasing the p− width also decreases the punchthrough voltage (for the same epi doping) but either the epi doping or the high doping portion of the base can be increased to compensate (up to the band to band tunneling limit). As implantation is normally used to fabricate the high doping portion of the base, it is preferable that the punchthrough voltage is largely determined by this layer rather than the lower doped epitaxial layer.

In one embodiment, a high dose arsenic implant of approximately 1e15/cm³ to 1e16/cm³ dose is implanted through an oxide into a grown n-type epi of doping concentration 1e16/cm³ over highly doped n substrate and diffused such that it has a desired junction depth of 0.35 microns. This diffusion forms the collector and should be sufficient to recrystallise the surface and remove defects. Subsequent to this implant, the oxide is removed and a boron implant is implanted to just below the arsenic junction with a dose of in the range of 3e12 and energy 77 keV to form the base. The implanted boron dopant characteristic can be controlled by the boron energy and dose. For a crystalline surface, boron can exhibit a plateau (i.e. width) of approximately 0.5 microns with sharp roll offs on both ends of the profile. The level of this plateau will be determined by the dose of the implant. This is very advantageous as this allows precise (through implantation) control of the width and the doping level of the base. In addition, the boron concentration in the plateau is relatively constant and is therefore advantageous for bidirectional diodes. Subsequent rapid thermal annealing is required to remove the defects caused by the implant as these will increase the leakage current. Rapid Thermal Annealing is required as these will remove the defects in a very short time whilst minimising the diffusion of boron. FIG. 5 shows the SIMS and SRP profiles of the collector and base dopings of the measured device (shown in FIG. 4). These SIMS and SRP results show the plateau of boron dopant. This process is very advantageous for narrow base width (<1 μm) punchthrough diodes. The combined thickness of the n− epi (after implantation) and transition region, termed Wₑₚᵢ, was designed such as to optimise the high current behaviour of the device whilst providing good punchthrough variability as described above.

Standard isolation schemes to isolate such diodes will be employed taking into account of the fact that the terminations must be such that the punchthrough voltage Vₚₜ is higher at the edges of the diode than at the middle and that avalanche breakdown voltage is not significantly decreased such that the edge breaks down before the middle of the diode.

The invention also provides a punch-aval structure shown in FIG. 16 with good bidirectionality and similar characteristics in forward and reverse mode. This five-layer structure can be manufactured using an implanted base and provides bi-directionality behaviour.

In all cases, PNP type diodes can also be used.

In summary, the device configuration and doping described above realises significant benefits from a practical viewpoint. These benefits include a reduction in required area and hence cost of the device of at least 70% in comparison with state of the art punchthrough devices. In addition, there is a reduction in capacitance of approximately 50%. Measurements have shown that a device area of approximately 0.1 mm2 is achievable for a 3.3V transient voltage suppressor which conforms to a IEC 61000-4-5 standard.

The invention is not limited to the embodiments described, but may be varied in construction and detail.

1. An open-base semiconductor diode device comprising emitter, base, and collector layers, wherein the layers are configured and doped such that the device has an IV characteristic with:
i. a punchthrough region beginning at a voltage Vₚₜ with positive resistance, followed by, and
ii. an avalanche region including a positive resistance stage beginning with conductivity modulation at V_{crit} and I_{crit} and having a resistance R_{crit},
iii. wherein the values of V_{crit}, I_{crit} and R_{crit} are set according to the layer configuration and doping.

2. A device as claimed in claim 1, wherein the layers are configured and doped so that V_{crit} is close to Vₚₜ.

3. A device as claimed in any preceding claim, wherein the doping of the base is set to a level such that injected current level per unit area (J_{crit}) at which the conductivity modulation occurs due to avalanche behaviour is increased.

4. A device as claimed in any preceding claim, wherein the device has a double-base structure, and the width of a lower-doped base region is minimised such that current density J_{crit} at which the conductivity modulation occurs due to avalanche is increased.

5. A device as claimed in claim 4, wherein the width of the lower-doped base region satisfies the following approximation:
$${J}_{crit} ∝ \frac{m ( {N}_{b} {W}_{b} + {N}_{b -} {W}_{epi} )}{{f}_{b} {W}_{b} + {f}_{epi} {W}_{epi}}$$
where m, f_{b} and fₑₚᵢ are real numbers, f_{b} and fₑₚᵢ are typically unity, W_{b} is the width of the higher doped base, Wₑₚᵢ is the width of the lower doped base, N_{b} is the doping concentration of the higher doped base region and N_{b-} is the doping concentration of the lower-doped base region

6. A device as claimed in any preceding claim, wherein the device comprises a N-N+ or a P-P+ double-emitter.

7. A device as claimed in claim 6, wherein thickness of N− or P− layers is minimised such that the current-carrying capability is maximised and the doping of this layer does not affect the current-carrying capability of the device.

8. A device as claimed in claim 7 wherein the width of the N− or P− region satisfies the following approximation:
$${J}_{crit} ∝ \frac{m ( {N}_{b} {W}_{b} )}{{f}_{b} {W}_{b} + {f}_{epi} {W}_{epi}}$$
where m, f_{b} and fₑₚᵢ are real numbers, f_{b} and fₑₚᵢ are typically unity, W_{b} is the width of the base, Wₑₚᵢ is the width of the N− or P− region, N_{b} is the doping concentration of the base region.

9. A device as claimed in any of claims 5 to 8, wherein the N− or P− layer doping is sufficiently low such that the N− or P− layer is fully depleted pre-breakdown and the capacitance of the device is minimised.

10. A device as claimed in any of claims 6 to 9, wherein the N− or P− layer is sufficiently wide such that, when biased for punchthrough breakdown, it is wider than a depletion region formed in this layer due to the applied bias.

11. A device as claimed in any of claims 6 to 9, wherein the N− or P− layer is sufficiently wide such that, when biased for punchthrough breakdown, it is wider than the sum of the manufacturing tolerance of this layer and the depletion region formed in this layer due to the applied bias so that the manufacturing tolerances in Vₚₜ are minimised.

12. A device as claimed in 6 to 11, wherein the N− or P− layer doping is approximately equal to the base doping.

13. A device as claimed in any of claims 6 to 12, wherein the device has a bi-directional open base structure with a double-emitter and a double-collector

14. A method of manufacturing an open-base semiconductor diode device comprising emitter, base, and collector layers, the method comprising the steps of configuring and doping the layers such that the device has an IV characteristic with:
i. a punchthrough region beginning at a voltage Vₚₜ with positive resistance, followed by, and
ii. an avalanche region including a positive resistance stage beginning with conductivity modulation at V_{crit} and I_{crit} and having a resistance
iii. wherein the values of V_{crit}, I_{crit} and R_{crit} are set according to the layer configuration and doping.

15. A method as claimed in claim 14, wherein boron is chosen for the base and is implanted through a crystalline lattice after the top surface has been implanted and recrystallised to form a layer such that a plateau of boron dopant of nearly constant concentration is achieved to allow good bidirectional behaviour.

16. A method as claimed in claims 14 or 15, wherein the layers are configured and doped so that V_{crit} is close to Vₚₜ.

17. A method as claimed in any of claims 14 to 16, wherein the doping of the base is set to a level such that injected current level per unit area (J_{crit}) at which the conductivity modulation occurs due to avalanche behaviour is increased.

18. A method as claimed in any of claims 14 to 17, wherein the device has a double-base structure, and the width of a lower-doped base region is minimised such that current density J_{crit} at which the conductivity modulation occurs due to avalanche is increased.

19. A method as claimed in claim 18 wherein the width of the lower-doped base region satisfies the following approximation:
$${J}_{crit} ∝ \frac{m ( {N}_{b} {W}_{b} + {N}_{b -} {W}_{epi} )}{{f}_{b} {W}_{b} + {f}_{epi} {W}_{epi}}$$
where m, f_{b} and fₑₚᵢ are real numbers, f_{b} and fₑₚᵢ are typically unity, W_{b} is the width of the higher doped base, Wₑₚᵢ is the width of the lower doped base, N_{b} is the doping concentration of the higher doped base region and N_{b-} is the doping concentration of the lower-doped base region

20. A method as claimed in any of claims 14 to 19, wherein the device comprises a N-N+ or a P-P+ double-emitter.

21. A method as claimed in claim 20, wherein thickness of N− or P− layers is minimised such that the current-carrying capability is maximised and the doping of this layer does not affect the current-carrying capability of the device.

22. A method as claimed in claim 21, wherein the width of the N− or P− region satisfies the following approximation:
$${J}_{crit} ∝ \frac{m ( {N}_{b} {W}_{b} )}{{f}_{b} {W}_{b} + {f}_{epi} {W}_{epi}}$$
where m, f_{b} and fₑₚᵢ are real numbers, f_{b} and fₑₚᵢ are typically unity, W_{b} is the width of the base, Wₑₚᵢ is the width of the N− or P− region, N_{b} is the doping concentration of the base region.

23. A method as claimed in any of claims 14 to 22, wherein the N− or P− layer doping is sufficiently low such that the N− or P− layer is fully depleted pre-breakdown and the capacitance of the device is minimised

24. A method as claimed in any of claims 14 to 23, wherein the N− or P− layer is sufficiently wide such that, when biased for punchthrough breakdown, it is wider than a depletion region formed in this layer due to the applied bias.

25. A method as claimed in any of claims 14 to 24, wherein the N− or P− layer is sufficiently wide such that, when biased for punchthrough breakdown, it is wider than the sum of the manufacturing tolerance of this layer and the depletion region formed in this layer due to the applied bias so that the manufacturing tolerances in Vₚₜ are minimised.

26. A method as claimed in any of claims 14 to 25, wherein the N− or P− layer doping is set approximately equal to the base doping.

27. A method as claimed in any of 14 to 26 wherein the device has a bi-directional open base structure with a double-emitter and a double collector.
